(19) United States
(12) Patent Application Publication
(10) Pub. No.: US 2012/0140385 A1
(43) Pub. Date: Jun. 7, 2012

(54) ELECTRONIC DEVICE ASSEMBLY WITH ADJUSTABLE SUPPORT

(75) Inventors: HUI YUAN, Shenzhen City (CN); ZHI-GANG YANG, Shenzhen City (CN); PING YU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/166,741

(22) Filed: Jun. 22, 2011

(30) Foreign Application Priority Data
Dec. 4, 2010 (CN) 201010574541.7

(51) Int. Cl. H05K 7/00

(52) U.S. Cl. 361/679.01

(57) ABSTRACT

An electronic device assembly which comprises an electronic device comprising a back shell; a rotary support comprising a connection frame attached to the back shell, a support arm including a first elongated section and a second elongated section distinctly oriented from the first elongated section, a rotary joint having a first end fixed to the connection frame and an opposite second end rotatably coupled to the first section, the rotary joint being rotatable about a first axis relative to the first section, and a base for mounted on a mounting surface, the second section being rotatably coupled to the base, the second section being rotatable about a second axis relative to the base, the second axis being substantially perpendicular to the first axis.

### BACKGROUND

1. Technical Field

The present disclosure relates to electronic devices with a support, especially to an electronic device assembly with an adjustable support.

2. Description of Related Art

Portable electronic devices such as digital photo frames include a support to support the digital photo frame on a table. Usually, the support can only support the photo frame in one or two orientations, which can limit its display conditions.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device assembly according to an exemplary embodiment.

FIG. 2 is similar to FIG. 1, but viewed from a different viewpoint.

FIG. 3 is a partial view of a connection frame of the electronic device assembly of FIG. 1.

FIG. 4 is an exploded view of the electronic device assembly of FIG. 1.

FIG. 5 is a partial view of a rotary joint of the electronic device assembly of FIG. 1.

### DETAILED DESCRIPTION

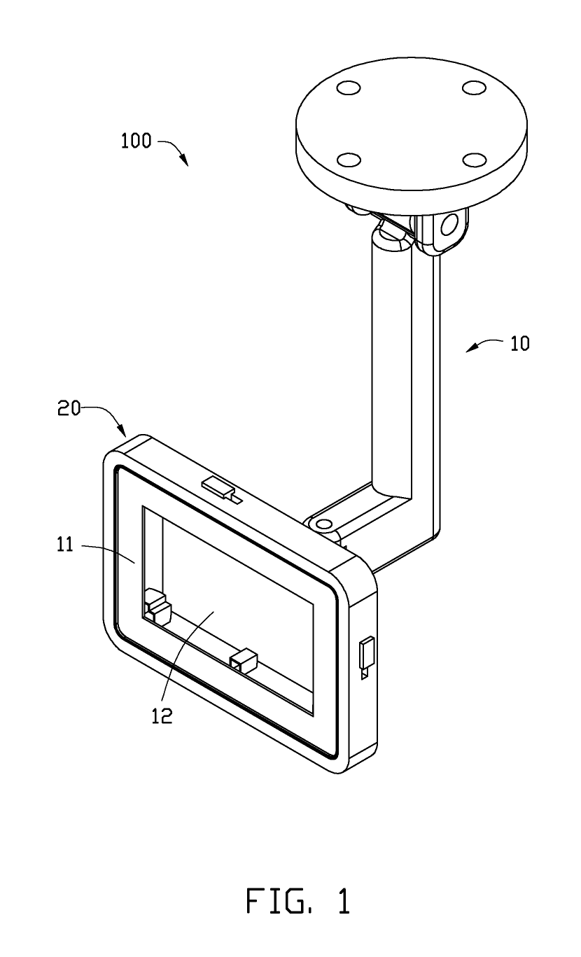

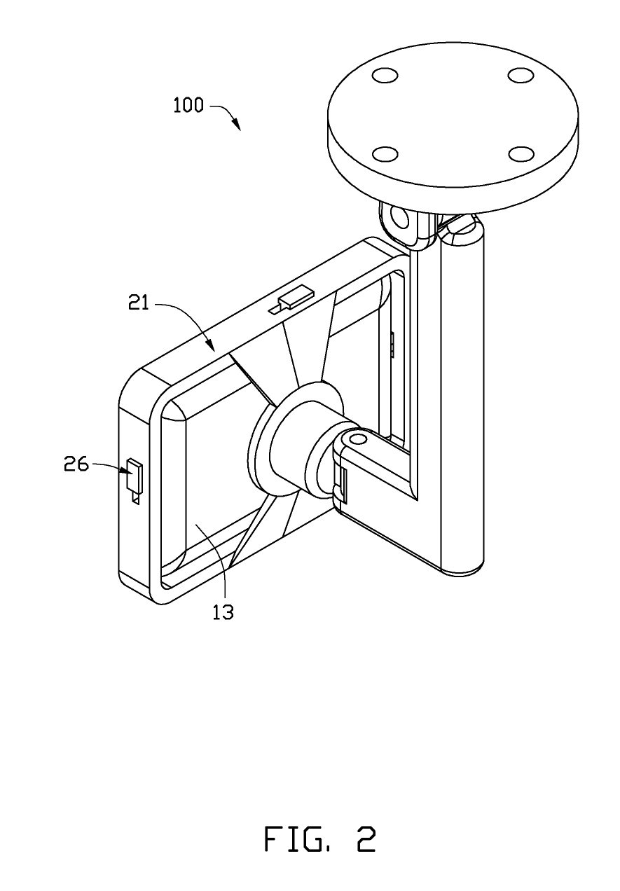

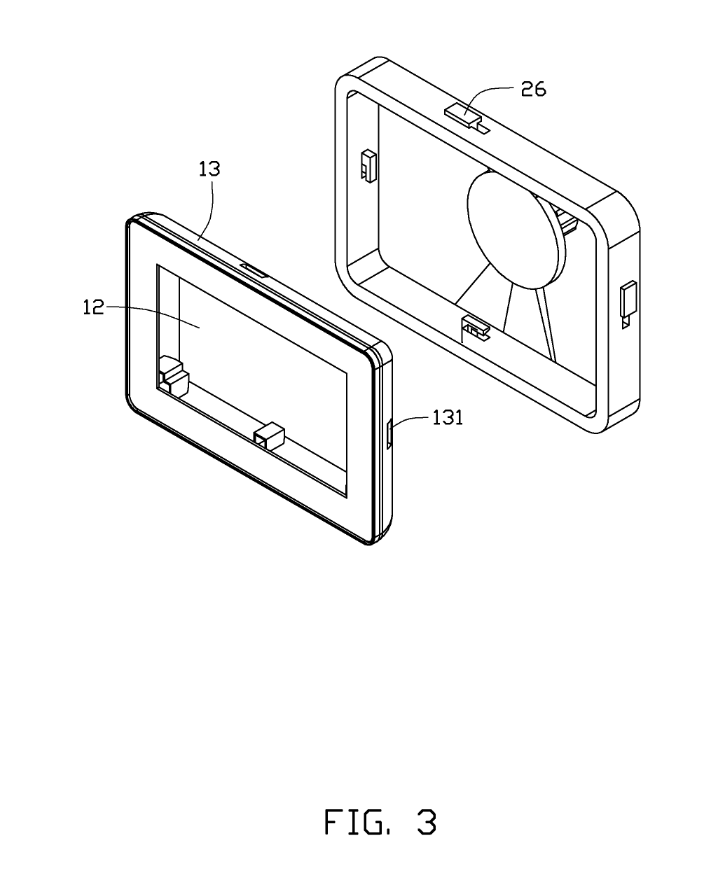

Referring to FIGS. 1-3, an electronic device assembly 100 according to an exemplary embodiment includes an electronic device 20 and a rotary support 10 connected to the back of the electronic device 20. Two ends of the rotary support 10 are capable of rotating about two mutually perpendicular axes.

The electronic device 20 includes a front shell 11, a display panel 12 and a back shell 13. The display panel 12 and a circuit board (not shown) are sandwiched between the front shell 11 and the back shell 13. In the embodiment, at least two first locking holes 131 are defined in the sidewall of the back shell 13, for engaging a plurality of corresponding fasteners 26 of the rotary support 10, thereby fixing the rotary support 10 to the electronic device 20, which will be described in detail as follows.

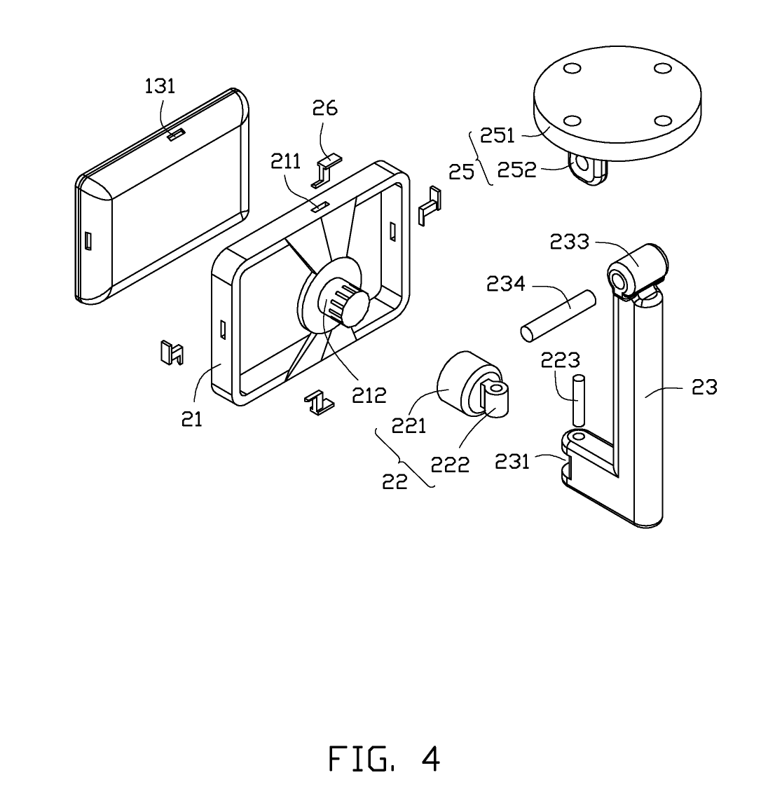

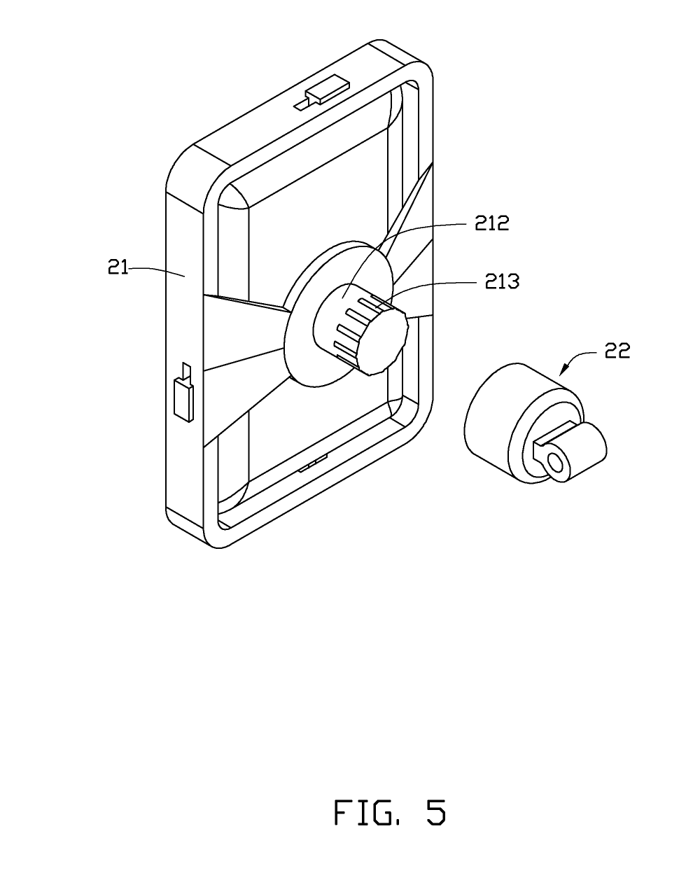

Referring to FIGS. 4 and 5, the rotary support 10 includes a connection frame 21, a rotary joint 22, a support arm 23, and a base 25. The base 25 is configured to fix the electronic device 100 on a wall or a ceiling. A first elongated section and a second elongated section distinctly oriented from the first elongated section of the support arm 23 are connected respectively and rotatably connected to the connection frame 21 and the base 25.

At least two second locking holes 211 corresponding to the first locking holes 131 are defined in the sidewalls of the connection frame 21. The fasteners 26 penetrate respectively through the first locking holes 131 and the second locking holes 211 to fix the connection frame 21 to the back shell 13. In the embodiment, the fasteners 26 are Z-shaped. The connection frame 21 further includes a cylindrical portion 212. The cylindrical portion 212 includes a number of bar-shaped protrusions on its lateral surface.

In the embodiment, the rotary joint 22 defines a blind hole 221 in a first end of the rotary joint 22. A number of slots are formed on the inner surface of the blind hole 221. When the cylindrical portion 212 is received in the blind hole 221, the bar-shaped protrusions are engaged with the slots, thereby connecting the rotary joint 22 to the frame 21. In an alternative embodiment, the rotary joint 22 may be connected to the cylindrical portion 212 by any suitable connection technique, such as screwing. A opposite second end of the rotary joint 22 includes a first axle receiver 222. The axis of the first axle receiver 222 is perpendicular to the central axis of the blind hole 221.

In the embodiment, the support arm 23 is L-shaped. The first elongated section of the support arm 23 defines a cutout 231 for receiving the first axle receiver 222. A first pivotable pin 223 penetrates through the first axle receiver 222 and the two holes defined in the two sides of the cutout 231, thereby rotatably connecting the support arm 23 to the rotary joint 22 and allowing the support arm 23 to rotate about the pin 223. The second elongated section of the support arm 23 includes a second axle receiver 233 and the second section is perpendicular to the first elongated section.

The base 25 includes a base plate 251 and two support walls 252. The base plate 251 can be fixed on a wall or a ceiling by screws. The two support walls 252 protrude from the base plate 251 and are parallel to each other. The free end of the two support walls 252 each defines a through hole. The second axle receiver 233 is arranged between the two support walls 252. A second pivotable pin 234 passes through the second axle receiver 233 of the support arm 23 and the through holes of the support walls 252, thereby rotatably connecting the support arm 23 to the base 25 and allowing the support arm 23 to rotate about the pin 234.

With the above configuration, the electronic device 20 can rotate about the pin 223, or together with the support arm 23, as a whole, rotate about the pin 234. In the embodiment, the pin 223 and the pin 234 are perpendicular to each other.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An electronic device assembly comprising:
an electronic device comprising a back shell; and
a rotary support comprising
a connection frame attached to the back shell,
a support arm including a first elongated section and a second elongated section distinctly oriented from the first elongated section,
a rotary joint having a first end fixed to the connection frame and an opposite second end rotatably coupled to the first section, the rotary joint being rotatable about a first axis relative to the first section, and
a base for mounted on a mounting surface, the second section being rotatably coupled to the base, the second section being rotatable about a second axis relative to the base, the second axis being substantially perpendicular to the first axis.

2. The electronic device assembly of claim 1, wherein the rotary joint includes a first axle receiver formed on the section end thereof and pivotally coupled to the first section, the support arm includes a second axle receiver formed on the second section thereof and pivotally coupled to the base.

3. The electronic device assembly of claim 2, wherein a cylindrical portion extends from the central portion of the connection frame, the cylindrical portion comprises a plurality of bar-shaped protrusions; the rotary joint includes a blind hole in the first end and a plurality of slots formed in the inner surface of the blind hole for engaging with the protrusions.

4. The electronic device assembly of claim 3, wherein the central axis of the first axle receiver is perpendicular to the central axis of the blind hole.

5. The electronic device assembly of claim 2, wherein the first section of the support arm defines a cutout receiving the first axle receiver.

6. The electronic device assembly of claim 1, wherein the second section is perpendicular to the first section.

7. The electronic device assembly of claim 2, wherein the base comprises a base plate and two support walls; the two support walls protrude from the base plate and are parallel to each other for receiving the second axle receiver.

8. The electronic device assembly of claim 1, wherein the electronic device further comprises a front shell and a display panel, the display panel sandwiched between the front shell and the back shell.
